(19) United States
(12) Patent Application Publication
(10) Pub. No.: US 2010/0238614 A1
(43) Pub. Date: Sep. 23, 2010

(54) ELECTRONIC DEVICE WITH KEY MODULE

(75) Inventors: JIA-YONG YE, Shenzhen City (CN); KUN-CHIH HSIEH, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/542,717

(22) Filed: Aug. 18, 2009

(30) Foreign Application Priority Data
Mar. 19, 2009 (CN) 200910300967.0

(51) Int. Cl. H05K 7/00

(52) U.S. Cl. 361/679.01; 200/341

(57) ABSTRACT

An electronic device comprises a housing and a key module. The housing defines a plurality of openings. The key module is mounted on the housing, comprises a plurality of keys and an elastic arm. The keys are received in the plurality of openings respectively and are connected with the elastic arm, and the elastic arm is fixed in the housing. The key module can be easily mounted in the housing, thus to reduce the mounting cost.

### BACKGROUND

1. Technical Field

The present disclosure relates to an electronic device having keys.

2. Description of Related Art

Keys are common input components for electronic devices. The keys are used for inputting characters and for performing functions, such as selecting a menu item. Some of the keys are disposed on a sidewall of the electronic device, and are mounted individually, which increases assembly time and cost.

What is needed is a key module which can reduce the mounting cost.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic, isometric view of an electronic device including a key module according to an exemplary embodiment.

FIG. 2 is a schematic, isometric view of the key module of FIG. 1.

FIG. 3 is a schematic, isometric view showing the key module mounted on an upper cover of the electronic device, viewed from an inside perspective.

### DETAILED DESCRIPTION

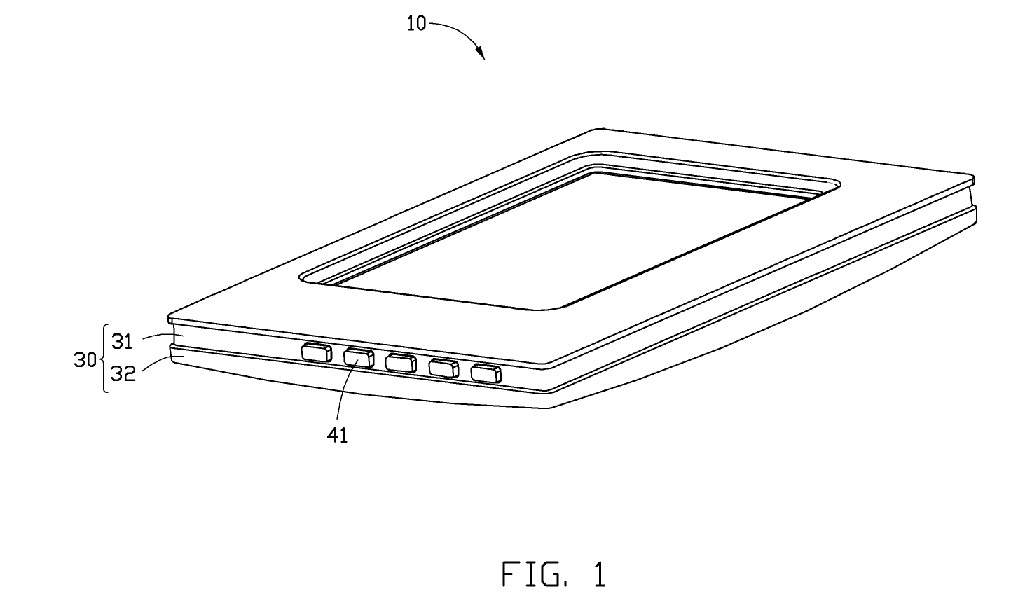

Referring to FIG. 1, an electronic device 10 is disclosed. The electronic device 10 includes a housing 30. The housing 30 includes an upper cover 31 and a bottom cover 32. A plurality of keys 41 is mounted on the upper cover 31.

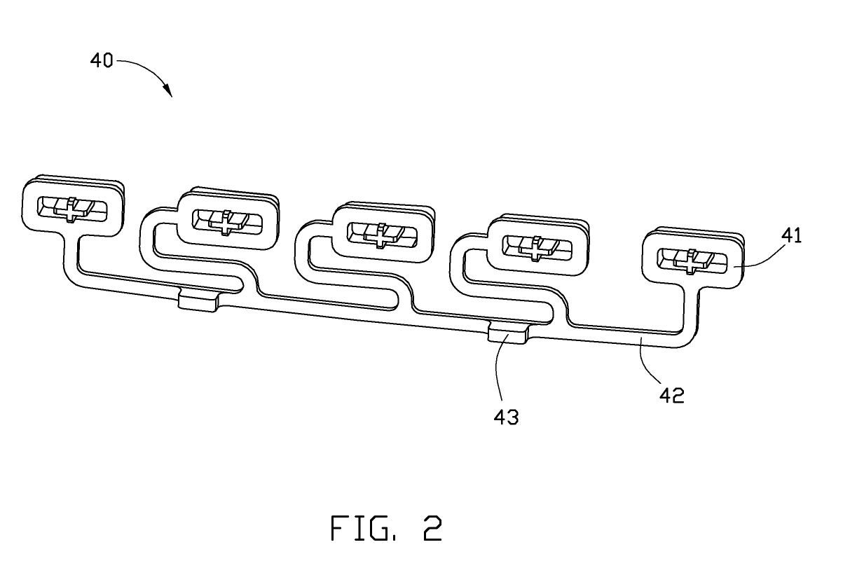

Referring to FIG. 2, the keys 41 belong to a key module 40. The key module 40 further includes an elastic arm 42. The keys 41 are connected to the elastic arm 42. The elastic arm 42 includes projections 43.

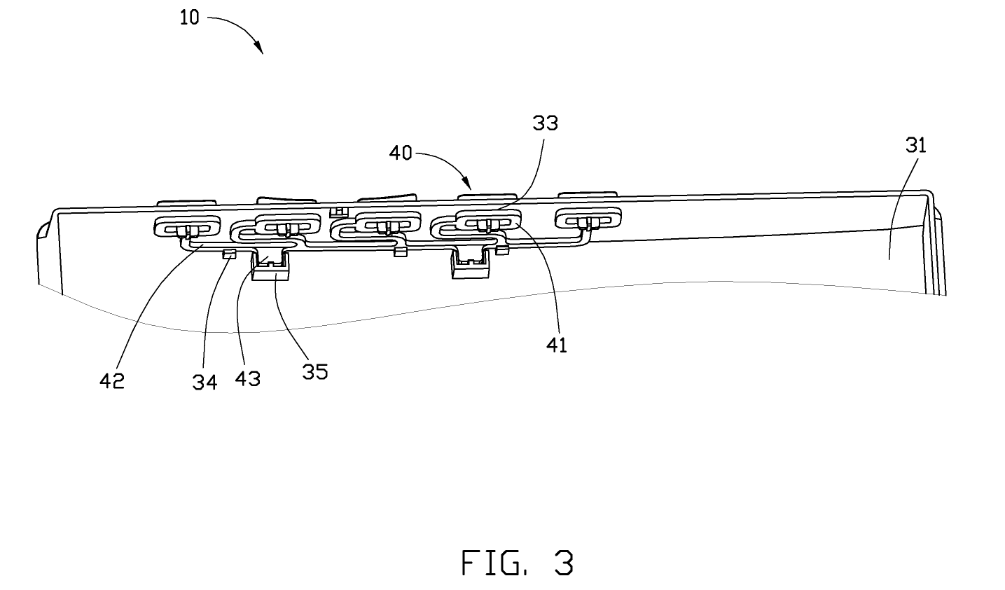

Referring to FIG. 3, the upper cover 31 defines openings 33 in sidewalls thereof. The upper cover 31 also includes stop blocks 34 and U shaped blocks 35 on an inner surface of the sidewalls. In assembly, the key module 40 is positioned in the upper cover 31, the keys 41 are respectively inserted into the openings 33, the projections are respectively inserted into the U shaped blocks 35, the elastic arm 42 is restricted by the stop blocks 34. In this way, the key module 40 is mounted in the upper cover 31. As all the keys 41 can be mounted on the housing 30 in one step, the mounting time is reduced. When a user presses a key 41, the stop blocks 34 and the U shaped blocks 35 will limit the deformation of the elastic arm 42, thus preventing an adjacent key 41 being affected by the pressing.

The key module 40 can also be mounted in the upper cover 31 by other means, such as hot melting.

Moreover, it is to be understood that the invention may be embodied in other forms without departing from the spirit thereof. Thus, the present examples and embodiments are to be considered in all respects as illustrative and not restrictive, and the invention is not to be limited to the details given herein.

What is claimed is:

1. An electronic device comprising:
a housing defining a plurality of openings; and
a key module mounted on the housing, comprising a plurality of keys and an elastic arm, wherein the keys are received in the plurality of openings respectively and are connected with the elastic arm, and the elastic arm is fixed in the housing.

2. The electronic device of claim 1, the key module further comprises projections formed on the elastic arm; U shaped blocks are formed in the housing; and the U shaped blocks receive the projections.

3. The electronic device of claim 1, the housing further comprises stop blocks formed in the housing for restricting the elastic arm and preventing a key's movement from affecting adjacent keys.

4. The electronic device of claim 1, wherein the elastic arm is fixed in the housing by hot melting.

5. A key module of an electronic device, the electronic device comprising a housing defining a plurality of openings, the key module comprising:
a plurality of keys configured for being received in the openings respectively; and
an elastic arm connected with the keys, configured for being fixed in the housing.

6. The key module of claim 5, further comprising projections formed on the elastic arm for mounting the key module to the housing.
